(19) United States
(12) Patent Application Publication
(10) Pub. No.: US 2021/0025511 A1
(43) Pub. Date: Jan. 28, 2021

(54) CIRCUIT BOARD POSITIONING DEVICE FOR ELECTRIC ACTUATOR

(71) Applicant: Sun Yeh Electrical Ind. Co., Ltd., Taichung City (TW)

(72) Inventor: Shui-Ching Chen, Taichung City (TW)

(73) Assignee: Sun Yeh Electrical Ind. Co., Ltd., Taichung City (TW)

(21) Appl. No.: 16/558,041

(22) Filed: Aug. 31, 2019

(30) Foreign Application Priority Data
Jul. 25, 2019 (TW) 108209745

(51) Int. Cl. F16K 31/02; H05K 7/20; H05K 5/00

(52) U.S. Cl. CPC F16K 31/02; H05K 5/0039; H05K 7/20436

(57) ABSTRACT

A circuit board positioning device for electric actuator comprises a base positioned inside a housing of an electric actuator; a first block made of an insulating material, a bottom side of the first block is disposed on a left side of the base, the first block comprises a first outer surface and a first inner surface, and the first inner surface is spacedly disposed with a plurality of first locators parallel to each other from top to bottom; and a second block made of an insulating material, a bottom side of the second block is disposed on a right side of the base, the second block comprises a second outer surface and a second inner surface, the second inner surface is spacedly disposed with a plurality of second locators parallel to each other from top to bottom, and the second locators are provided corresponding to the first locators.

### RELATED APPLICATIONS

This application claims benefit of Taiwan Patent Application No. 108209745 filed Jul. 25, 2019.

The above applications and all patents, patent applications, articles, books, specifications, other publications, documents, and things referenced herein are hereby incorporated herein in their entirety for all purposes. To the extent of any inconsistency or conflict in the definition or use of a term between any of the incorporated publications, documents, or things and the text of the present document, the definition or use of the term in the present document shall prevail.

### BACKGROUND OF THE INVENTION

### Field of Invention

The present invention provides a circuit board positioning device for electric actuator.

### Related Art

As shown in FIGS. 1 and 2, an electric actuator 10 is used to drive a valve or a damper, and a terminal block disc 111 and a control unit 20 are disposed in a housing 11 of the electric actuator 10.

The control unit 20 is composed of a plurality of circuit boards 21 that are locked by a plurality of locators 22 and screws as shown in FIGS. 3 & 4.

However, when the circuit boards 21 of the control unit 20 fail, the locators 22 and the screws need to be disassembled one by one, and the maintenance process is extremely inconvenient and time consuming.

### SUMMARY OF THE INVENTION

The primary objective of one embodiment of the present invention is capable of making the assembly and positioning as well as repair and replacement of the circuit boards faster and more convenient, and actively improving the work efficiency, and accordingly reducing the maintenance cost.

In accordance with one embodiment of the present invention, there is provided a circuit board positioning device for electric actuator, comprising a base positioned inside a housing of an electric actuator; a first block made of an insulating material, a bottom side of the first block being disposed on a left side of the base, the first block comprising a first outer surface and a first inner surface, and the first inner surface being spacedly disposed with a plurality of first locators parallel to each other from top to bottom; and a second block made of an insulating material, a bottom side of the second block being disposed on a right side of the base, the second block comprising a second outer surface and a second inner surface, the second inner surface being spacedly disposed with a plurality of second locators parallel to each other from top to bottom, and the second locators being provided corresponding to the first locators.

The foregoing objective, features, and advantages of the present invention will be more readily understood upon a thoughtful deliberation of the following detailed description of the present invention in conjunction with the accompanying drawings.

### BRIEF DESCRIPTION OF THE DRAWINGS

FIG. 1 is a perspective view of a conventional electric actuator;

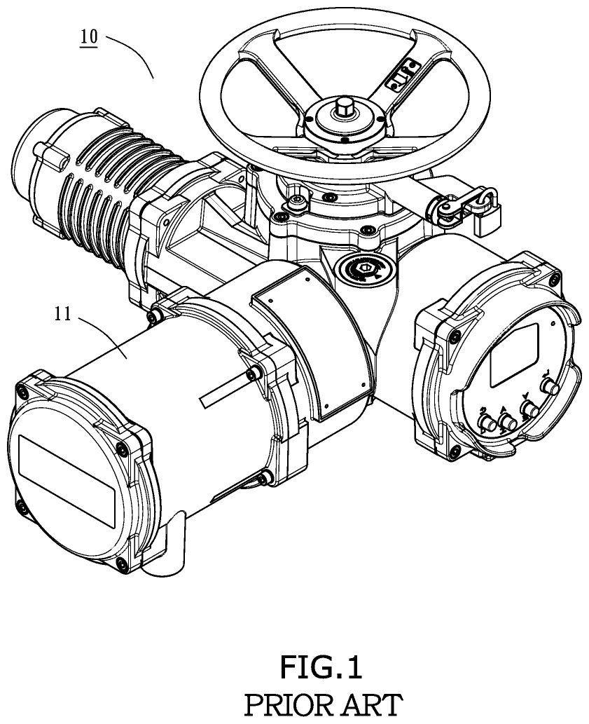

FIG. 2 is a partial exploded perspective view of FIG. 1;

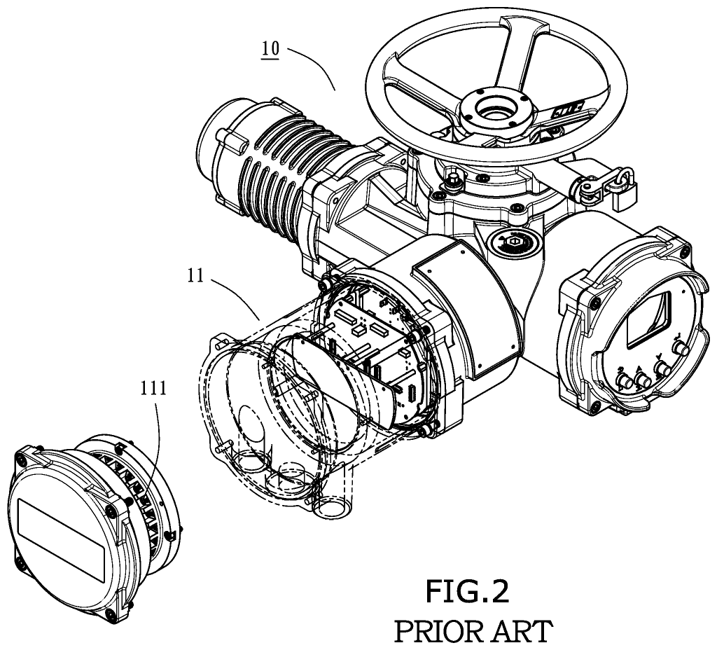

FIG. 3 is a perspective view of a control unit of FIG. 2;

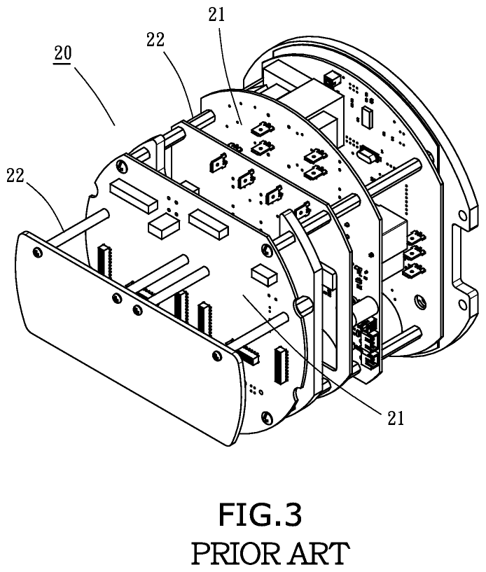

FIG. 4 is an exploded perspective view of FIG. 3;

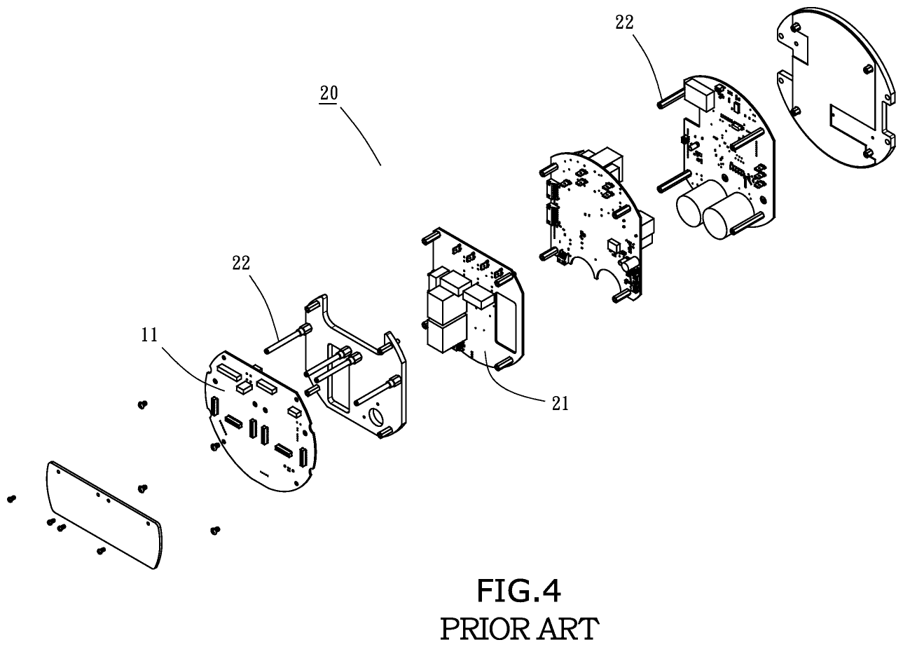

FIG. 5 is a perspective assembly view of one embodiment of a circuit board positioning device for electric actuator according to a first embodiment of the present invention;

FIG. 6 is an exploded perspective view of FIG. 5;

FIG. 7 is a bottom view of a base in FIG. 6;

FIG. 8 is a perspective view of one embodiment of a second block in FIG. 6 being viewed from a left side;

FIG. 9 is a side view of FIG. 5;

FIG. 10 is a schematic view of the first embodiment of the present invention being mounted inside a housing of an electric actuator;

FIG. 11 is a schematic view of insertion of circuit boards;

FIG. 12 is a partial enlarged view of part A of FIG. 11;

FIG. 13 is a schematic view of a faulty circuit board being pulled out;

FIG. 14 is a perspective view of structural features of the circuit board positioning device for electric actuator according to a second embodiment of the present invention;

FIG. 15 is a perspective assembly view of FIG. 14;

FIG. 16 is an exploded perspective view of the circuit board positioning device for electric actuator according to a third embodiment of the present invention;

FIG. 17 is a perspective assembly view of FIG. 16;

FIG. 18 is a perspective view of the second block and a third heat sink in FIG. 17 being viewed from a left side; and

FIG. 19 is a schematic view of the circuit board positioning device for electric actuator according to a fourth embodiment of the present invention.

### DETAILED DESCRIPTION OF THE INVENTION

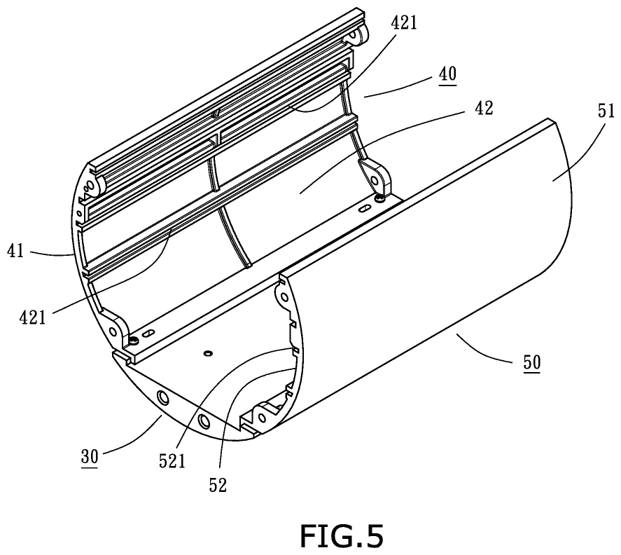

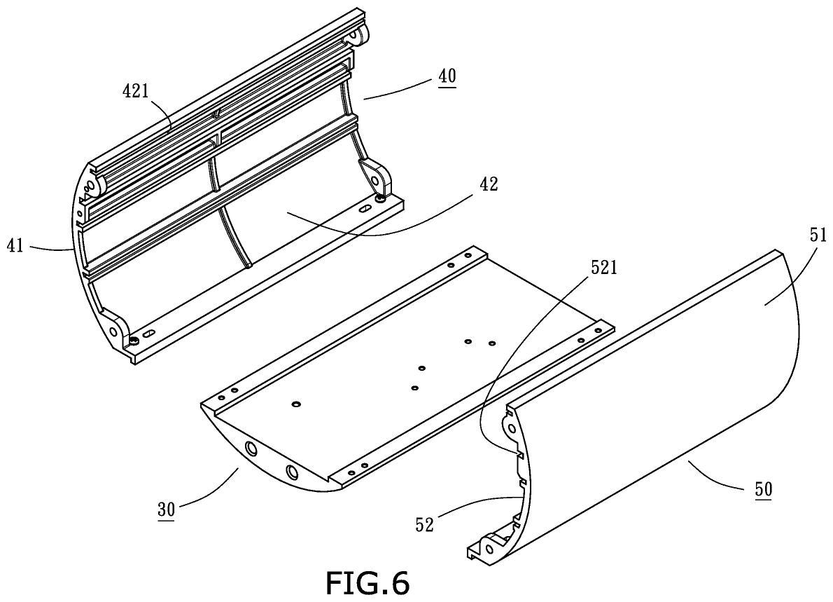

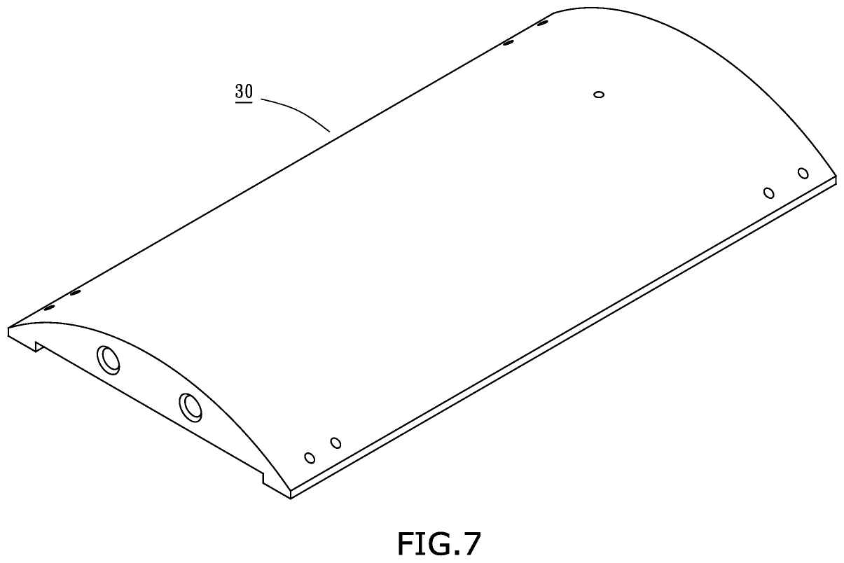

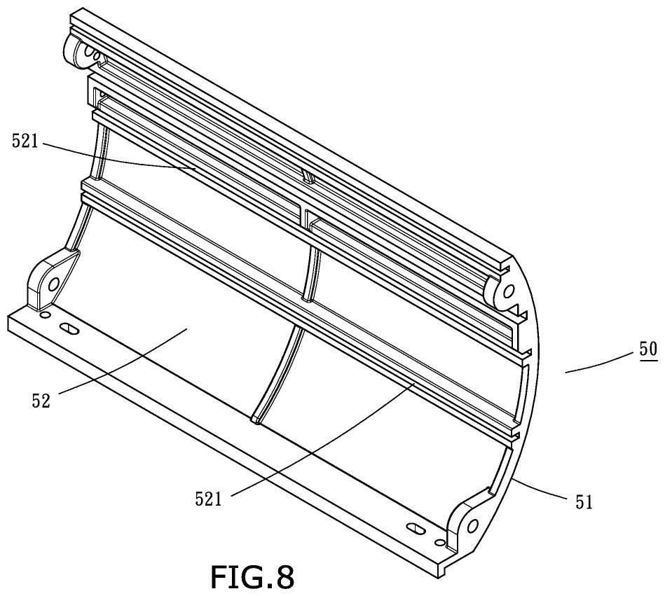

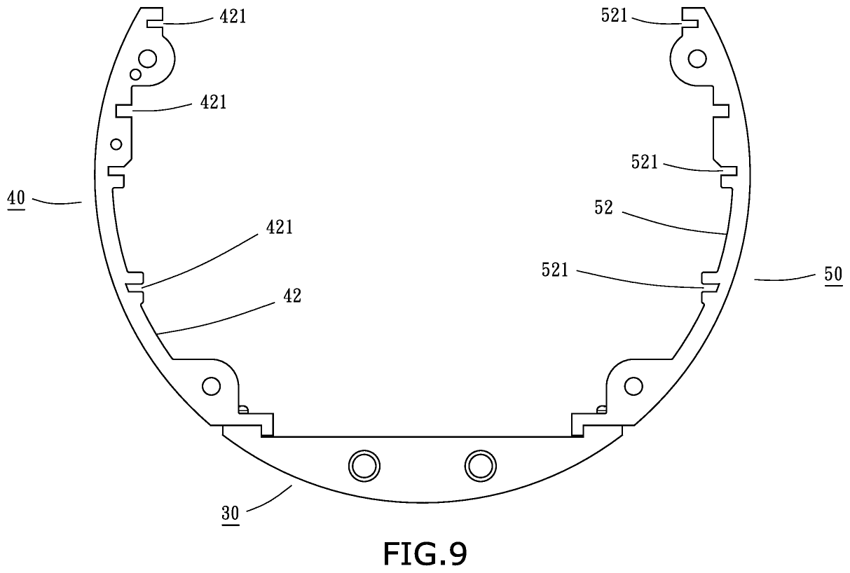

A first embodiment of a circuit board positioning device for electric actuator is shown in FIGS. 5 to 9, mainly comprising a base 30, a first block 40 and a second block 50.

The base 30 is positioned inside a housing 11 of an electric actuator.

The first block 40 is in a concave arc shape, and is made of a heat-resistant insulating material such as bakelite. A bottom side of the first block 40 is disposed on a left side of the base 30. The first block 40 comprises a first outer surface 41 and a first inner surface 42. The first inner surface 42 is spacedly disposed with a plurality of first locators 421 parallel to each other from top to bottom, and the first locators 421 are in a groove shape.

The second block 50 is made of a heat-resistant insulating material such as bakelite and is in a concave arc shape. A bottom side of the second block 50 is disposed on a right side of the base 30. The second block 50 comprises a second outer surface 51 and a second inner surface 52. The second inner surface 52 is spacedly disposed with a plurality of second locators 521 parallel to each other from top to bottom, and the second locators 521 are provided corresponding to the first locators 421, and the second locators 521 are in a groove shape.

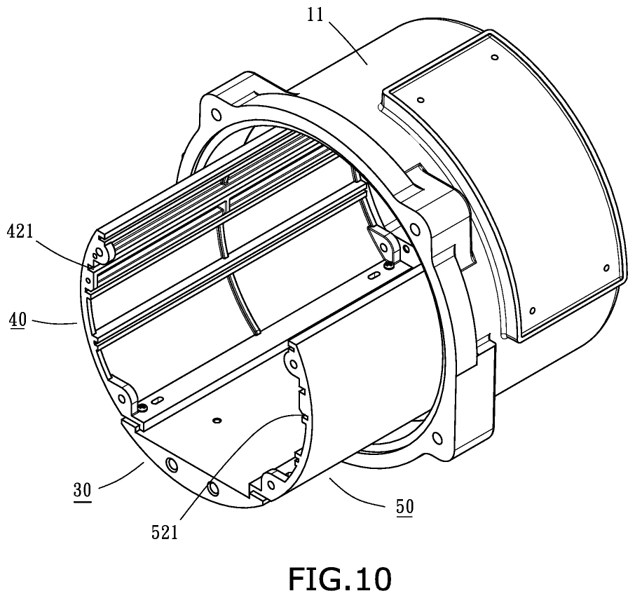

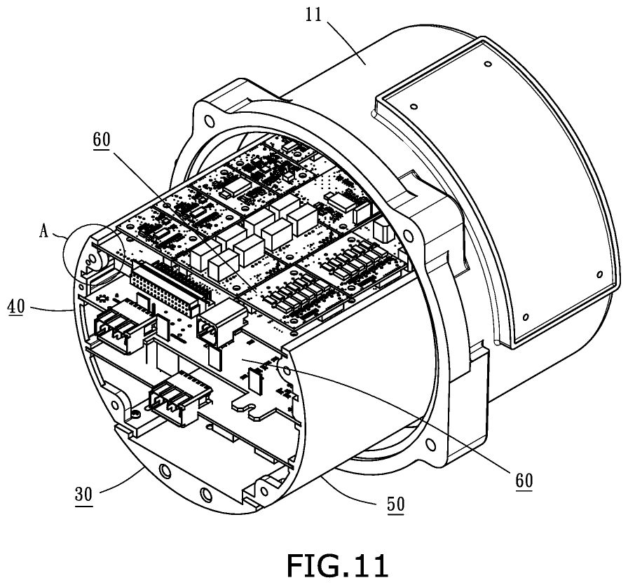

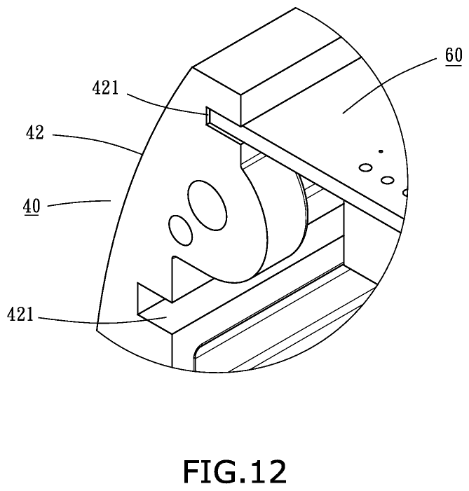

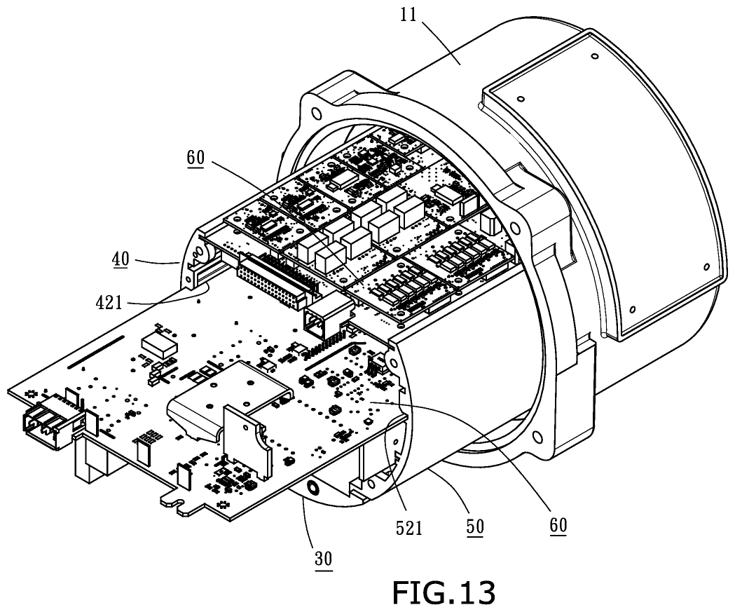

When in use, as shown in FIGS. 10 to 13, one embodiment of the base 30 is locked inside the housing 11 of the electric actuator by screws, and then circuit boards 60 are inserted one by one into the corresponding first locators 421 and second locators 521 of the first block 40 and the second block 50. When the circuit board 60 is malfunctioned, it only needs to easily pull out the faulty circuit board 60 from the first block 40 and the second block 50 as shown in FIG. 13. The operation is quite convenient and can reduce the disassembly time.

Preferably, a material used for one embodiment of the first block 40 and the second block 50 is nylon reinforced with fiberglass.

In summary, the present invention has the efficacies of easy installation and convenient maintenance.

Moreover, since one embodiment of the circuit board 60 generates heat energy during operation, and excessive heat energy often causes the circuit to crash due to overheating, the base 30 can be made of a material with good thermal conductivity, thereby contributing to dissipation of heat energy in order to keep a temperature inside the housing 11 of the electric actuator as equalized as possible to avoid local overheating.

Preferably, a material used for one embodiment of the base 30 is aluminum.

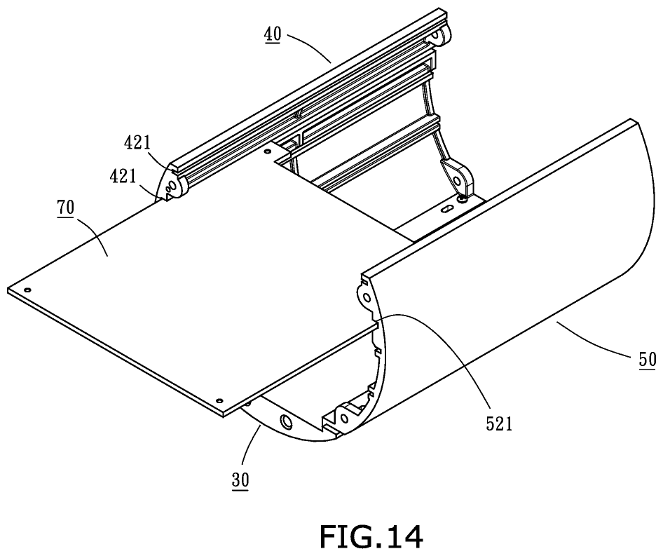

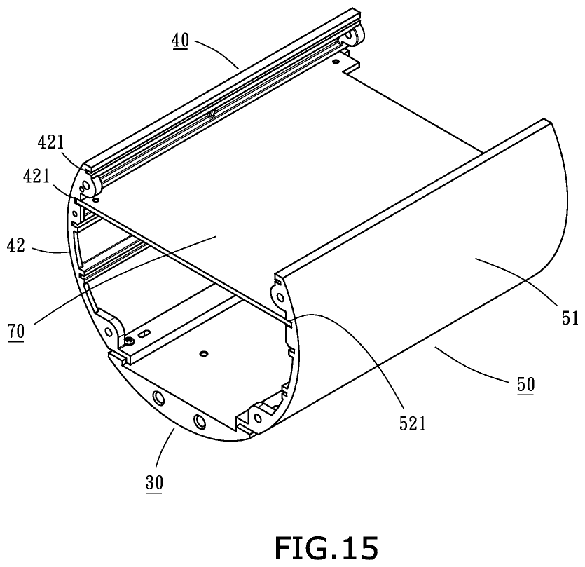

FIGS. 14 and 15 are a second embodiment, which differs from the first embodiment in that a first heat sink 70 is further included, which is made of a material with good thermal conductivity such as aluminum. The first heat sink 70 is inserted into the corresponding first locator 421 and second locator 521 of the first block 40 and the second block 50. An installation position of the first heat sink 70 can be selected close to the circuit board 60 having a warmer heat source, and thermal energy is dissipated by heat conduction in order to equalize a temperature inside the housing 11 as quickly as possible.

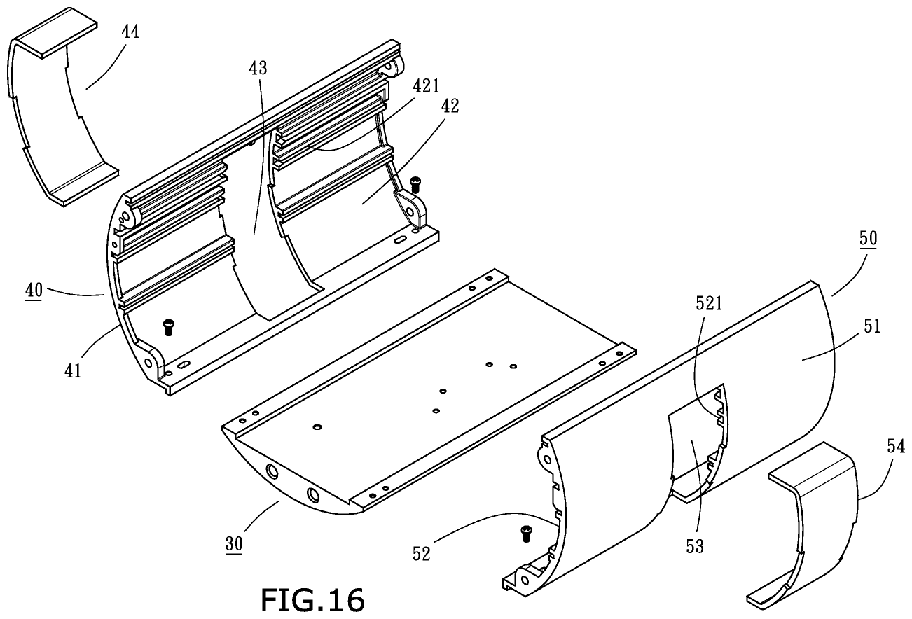

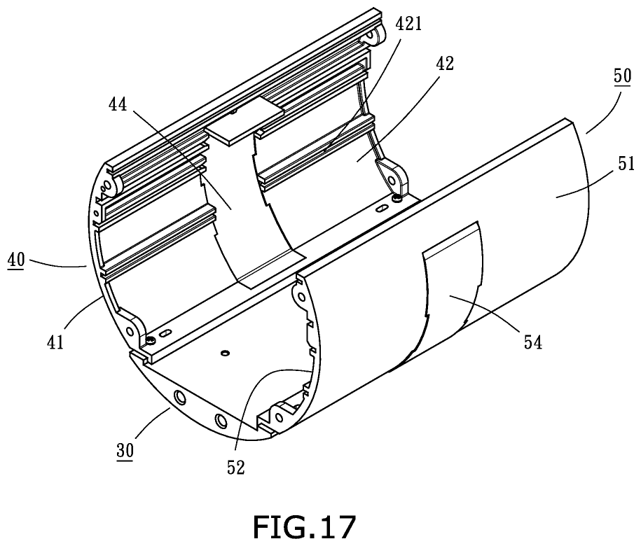

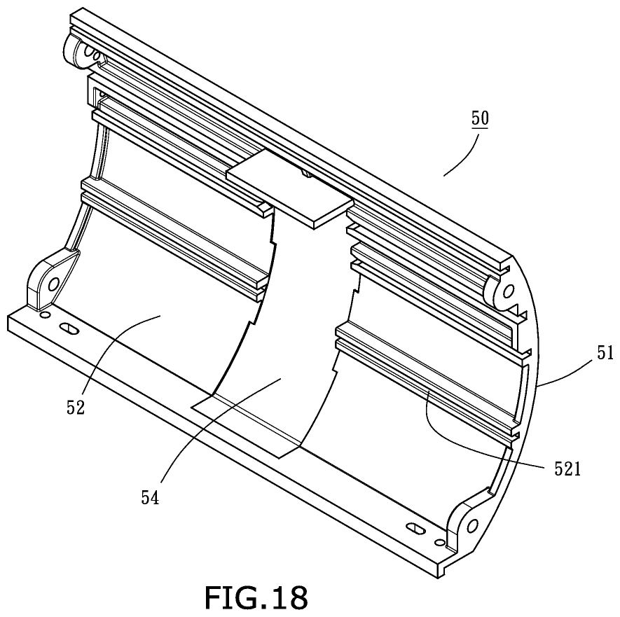

FIGS. 16 to 18 are a third embodiment, which differs from the first embodiment in that the first block 40 is provided with a first slot 43, the first slot 43 penetrates the first outer surface 41 and the first inner surface 42, and the first slot 43 is capable of positioning a second heat sink 44. The second heat sink 44 is made of a material with good thermal conductivity. The second block 50 is provided with a second slot 53. The second slot 53 penetrates the second outer surface 51 and the second inner surface 52, and the second slot 53 is capable of positioning a third heat sink 54. The third heat sink 54 is made of a material with good thermal conductivity such as aluminum in order to equalize a temperature inside the housing 11 as faster as possible.

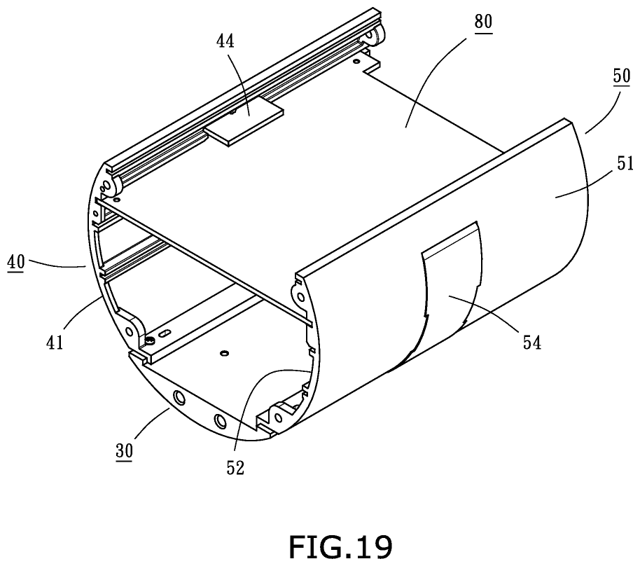

FIG. 19 is a fourth embodiment, which differs from the third embodiment in that a fourth heat sink 80 is further included, which is made of a material with good thermal conductivity such as aluminum. The fourth heat sink 80 is inserted into the corresponding first locator 421 and second locator 521 of the first block 40 and the second block 50.

The specific embodiments described herein are merely illustrative of the spirit of the present invention. Technical personnel skilled in the art to which the present invention pertains can make various modifications or additions to the specific embodiments described or replace them in a similar manner, without departing from the spirit of the present invention or beyond the scope defined by the appended claims.

### LIST OF REFERENCED PARTS

housing 11
base 30
first block 40
first outer surface 41
first inner surface 42
first locator 421
first slot 43
second heat sink 44
second block 50
second outer surface 51
second inner surface 52
second locator 521
second slot 53
third heat sink 54
circuit board 60
first heat sink 70
fourth heat sink 80

What is claimed is:

1. A circuit board positioning device for an electric actuator, comprising:
a base positioned inside a housing of an electric actuator;
a first block made of an insulating material, a bottom side of the first block being disposed on a left side of the base, the first block comprising a first outer surface and a first inner surface, and the first inner surface being spacedly disposed with a plurality of first locators parallel to each other from top to bottom; and
a second block made of an insulating material, a bottom side of the second block being disposed on a right side of the base, the second block comprising a second outer surface and a second inner surface, the second inner surface being spacedly disposed with a plurality of second locators parallel to each other from top to bottom, and the second locators corresponding to the first locators.

2. The circuit board positioning device for an electric actuator as claimed in claim 1, wherein the first and second blocks are made of a heat-resistant insulating material.

3. The circuit board positioning device for an electric actuator as claimed in claim 2, wherein a material used for the first and second blocks is nylon reinforced with fiberglass or is Bakelite.

4. The circuit board positioning device for an electric actuator as claimed in claim 1, wherein the base is made of a material with good thermal conductivity, the first and second blocks are in a concave arc shape, and the first and second locators are in a groove shape.

5. The circuit board positioning device for an electric actuator as claimed in claim 4, wherein a material used for the base is aluminum.

6. The circuit board positioning device for an electric actuator as claimed in claim 1, wherein a first heat sink with good thermal conductivity is disposed between the first and second blocks, and is inserted into the corresponding first and second locators of the first and second blocks.

7. The circuit board positioning device for an electric actuator as claimed in claim 4, wherein a first heat sink with good thermal conductivity is disposed between the first and second blocks, and is inserted into the corresponding first and second locators of the first and second blocks.

8. The circuit board positioning device for an electric actuator as claimed in claim 5, wherein a first heat sink with good thermal conductivity is disposed between the first and second blocks, and is inserted and positioned into the corresponding first and second locators of the first and second blocks.

9. The circuit board positioning device for an electric actuator as claimed in claim 1, wherein the first block is disposed with a first slot, the first slot penetrating the first outer surface and the first inner surface, and the first slot being capable of positioning a second heat sink with good thermal conductivity, and wherein the second block is disposed with a second slot, the second slot penetrating the second outer surface and the second inner surface, and the second slot being capable of positioning a third heat sink with good thermal conductivity.

10. The circuit board positioning device for an electric actuator as claimed in claim 9, wherein the first and second blocks are made of a heat-resistant insulating material.

11. The circuit board positioning device for an electric actuator as claimed in claim 10, wherein a material used for the first and second blocks is nylon reinforced with fiberglass or is Bakelite.

12. The circuit board positioning device for an electric actuator as claimed in claim 9, wherein the base is made of a material with good thermal conductivity, the first and second blocks are in a concave arc shape, and the first and second locators are in a groove shape.

13. The circuit board positioning device for an electric actuator as claimed in claim 12, wherein a material used for the base is aluminum.

14. The circuit board positioning device for an electric actuator as claimed in claim 10, wherein the base is made of a material with good thermal conductivity, the first and second blocks are in a concave arc shape, and the first and second locators are in a groove shape.

15. The circuit board positioning device for an electric actuator as claimed in claim 11, wherein the base is made of a material with good thermal conductivity, the first and second blocks are in a concave arc shape, and the first and second locators are in a groove shape.

16. The circuit board positioning device for an electric actuator as claimed in claim 9, wherein a fourth heat sink with good thermal conductivity is disposed between the first and second blocks, and the fourth heat sink is inserted into the corresponding first and second locators of the first and second blocks.

17. The circuit board positioning device for an electric actuator as claimed in claim 10, wherein a fourth with good thermal conductivity is disposed between the first and second blocks, and is inserted into the corresponding first and second locators of the first and second blocks.

18. The circuit board positioning device for an electric actuator as claimed in claim 11, wherein a fourth with good thermal conductivity is disposed between the first and second blocks, and is inserted into the corresponding first and second locators of the first and second blocks.

19. The circuit board positioning device for an electric actuator as claimed in claim 12, wherein a fourth with good thermal conductivity is disposed between the first and second blocks, and is inserted into the corresponding first and second locators of the first and second blocks.

20. The circuit board positioning device for an electric actuator as claimed in claim 13, wherein a fourth with good thermal conductivity is disposed between the first and second blocks, and is inserted into the corresponding first and second locators of the first and second blocks.
